(19) United States
(12) Patent Application Publication
(10) Pub. No.: US 2018/0190227 A1
(43) Pub. Date: Jul. 5, 2018

(54) SHIFT REGISTER UNIT, GATE DRIVING CIRCUIT, AND DRIVING METHOD THEREOF

(71) Applicants: BOE TECHNOLOGY GROUP CO., LTD., Beijing (CN); HEFEI BOE OPTOELECTRONICS TECHNOLOGY CO., LTD., Hefei, Anhui (CN)

(72) Inventors: Silin FENG, Beijing (CN); Hongmin LI, Beijing (CN)

(73) Assignees: BOE TECHNOLOGY GROUP CO., LTD, Beijing (CN); HEFEI BOE OPTOELECTRONICS TECHNOLOGY CO., LTD., Anhui (CN)

(21) Appl. No.: 15/563,243

(22) PCT Filed: May 4, 2017
(86) PCT No.: PCT/CN2017/083062

§ 371 Date: Sep. 29, 2017

(30) Foreign Application Priority Data
Jun. 12, 2016 (CN) 201610408939.0

(51) Int. Cl. G09G 3/36; G11C 19/28

(52) U.S. Cl. CPC G09G 3/3674; G11C 19/28; G09G 3/36

(57) ABSTRACT

A shift register unit, a gate driving circuit, and a driving method thereof. By way of a configuration of a fourth reset circuit in the shift register unit, applying an active level of the fourth reset circuit on a first control terminal during an end phase of a duration in which a scan pulse is output at a scan pulse output terminal allows the fourth reset circuit to pull down an amplitude of a voltage of the scan pulse. In this way, angle-cutting of the scan pulse is realized.

### CROSS-REFERENCE TO RELATED APPLICATIONS

The present application is the U.S. national phase entry of PCT/CN2017/083062, with an international filing date of May 4, 2017, which claims the benefit of Chinese Patent Application No. 201610408939.0, filed on Jun. 12, 2016, the entire disclosures of which are incorporated herein by reference.

### TECHNICAL FIELD

The present disclosure relates to the field of display technology, and particularly to a shift register unit, a gate driving circuit, and a driving method thereof.

### BACKGROUND

Gate On Array (GOA) is a technology where gate drivers are directly fabricated on an array substrate. This technology can eliminate a need for a corresponding chip and a circuit board, and facilitate cost reduction and bezel narrowing.

For GOAs in existing LCD display circuits, there is typically a load on a gate line, such as capacitance and resistance, and the near end is less affected by the load on the gate line while the far end is more affected by the load on the gate line. In this case, the gate driving signal has different amounts of voltage transition in decreasing from V_{GH} to V_{GL}. Thereby, the amount of variation ΔVp of the data voltage due to the voltage transition will also be different at the near end and the far end of the gate line. This will easily lead to flickering on the screen and affect the picture quality.

### SUMMARY

It is an object of the present disclosure to provide a shift register unit having, in particular, an angle-cutting function to at least avoid or mitigate one or more of the above-mentioned technical deficiencies.

To address this, the present disclosure provides in a first aspect a shift register unit. The shift register unit comprises an input circuit, an output circuit, a first energy storage circuit, a first reset circuit, a second reset circuit, a third reset circuit, a fourth reset circuit, and a second node control circuit. Specifically, the input circuit is connected to a scan pulse input terminal and a first node for setting the first node at a first level in response to the scan pulse input terminal being at the first level. The output circuit is connected to the first node, a first clock signal terminal, and a scan pulse output terminal for bringing the first clock signal input terminal and the scan pulse output terminal into conduction in response to the first node being at the first level. The first energy storage circuit is connected to the first node and the scan pulse output terminal for maintaining charges of the first node in response to the first node being floated. The first reset circuit is connected to a reset control terminal, the first node and a second level direct current voltage terminal for bringing the first node and the second level direct current voltage terminal into conduction in response to the reset control terminal being at the first level. The second reset circuit is connected to a second clock signal terminal, the scan pulse output terminal and the second level direct current voltage terminal for bringing the scan pulse output terminal and the second level direct current voltage terminal into conduction in response to the second clock signal terminal being at the first level. Further, the third reset circuit is connected to the first node, a second node, the scan pulse output terminal and the second level direct current voltage terminal for bringing the first node and the second level direct current voltage terminal into conduction, and the scan pulse output terminal and the second level direct current voltage terminal into conduction, in response to the second node being at the first level. Further, the second node control circuit is connected to the first clock signal terminal, the first node, the second node, and the second level direct current voltage terminal for bringing the second node and the second level direct current voltage terminal into conduction in response to the first node being at the first level, and for bringing the first clock signal terminal and the second node into conduction in response to the first clock signal terminal being at the first level. Still further, the fourth reset circuit is connected to a first control terminal, the first node, the scan pulse output terminal and the second level direct current voltage terminal for bringing the first node and the second level direct current voltage terminal into conduction, and the scan pulse output terminal and the second level direct current voltage terminal into conduction, in response to the first control terminal being at an active level of the fourth reset circuit.

In some embodiments, the shift register unit further comprises a second energy storage circuit connected to the second node for maintaining charges of the second node in response to the second node being floated.

In some embodiments, the second energy storage circuit comprises a first capacitor, one terminal of the first capacitor being connected to the second node and the other to the second level direct current voltage terminal.

In some embodiments, the input circuit comprises a first switch transistor. A gate of the first switch transistor is connected to the scan pulse input terminal, one of a source and a drain of the first switch transistor is connected to the scan pulse input terminal, and the other to the first node. A conduction level of the first switch transistor is the first level.

In some embodiments, the output circuit comprises a second switch transistor. A gate of the second switch transistor is connected to the first node, one of a source and a drain of the second switch transistor is connected to the first clock signal terminal, and the other to the scan pulse output terminal. A conduction level of the second switch transistor is the first level.

In some embodiments, the first energy storage circuit comprises a second capacitor.

In some embodiments, the first reset circuit comprises a third switch transistor. A gate of the third switch transistor is connected to the reset control terminal, one of a source and a drain of the third switch transistor is connected to the first node, and the other to the second level direct current voltage terminal. A conduction level of the third switch transistor is the first level.

In some embodiments, the second reset circuit comprises a fourth switch transistor. A gate of the fourth switch transistor is connected to the second clock signal terminal, one of a source and a drain of the fourth switch transistor is connected to the scan pulse output terminal, and the other to the second level direct current voltage terminal. A conduction level of the fourth switch transistor is the first level.

In some embodiments, the third reset circuit comprises a fifth switch transistor and a sixth switch transistor. A gate of the fifth switch transistor is connected to the second node, one of a source and a drain of the fifth switch transistor is connected to the first node, and the other to the second level direct current voltage terminal. A conduction level of the fifth switch transistor is the first level. Further, a gate of the sixth switch transistor is connected to the first node, one of a source and a drain of the sixth switch transistor is connected to the scan pulse output terminal, and the other to the second level direct current voltage terminal. A conduction level of the sixth switch transistor is the first level.

In some embodiments, the second node control circuit comprises a seventh switch transistor and an eighth switch transistor. Specifically, a gate of the seventh switch transistor is connected to the first clock signal terminal, one of a source and a drain of the seventh switch transistor is connected to the first clock signal terminal, and the other to the second node. A conduction level of the seventh switch transistor is the first level. Further, a gate of the eighth switch transistor is connected to the first node, one of a source and a drain of the eighth switch transistor is connected to the second node, and the other to the second level direct current voltage terminal. A conduction level of the eighth switch transistor is the first level.

In some embodiments, the fourth reset circuit comprises a ninth transistor and a tenth transistor. Specifically, a gate of the ninth switch transistor is connected to the first control terminal, one of a source and a drain of the ninth switch transistor is connected to the first node, and the other to the second level direct current voltage terminal. A conduction level of the ninth switch transistor is the active level. Further, a gate of the tenth switch transistor is connected to the first control terminal, one of a source and a drain of the tenth switch transistor is connected to the scan pulse output terminal, and the other to the second level direct current voltage terminal. A conduction level of the tenth switch transistor is the active level.

In some embodiments, the first level comprises a high level, the second level comprises a low level, and the active level of the fourth reset circuit comprises a high level.

According to a second aspect, the disclosure provides a gate driving circuit that comprises a plurality of any of the shift register units as described above that are cascaded with each other.

According to a third aspect, the disclosure further provides a driving method for the gate driving circuit as described above. The driving method comprising inputting a start pulse to the input terminal of a first one of the shift register units, inputting corresponding clock signals to the first clock signal terminals and the second clock signal terminals so that the gate driving circuit sequentially outputs a plurality of scan pulses, and inputting a clock signal to the first control terminal of each of the shift register units so that the first control terminal of each of the shift register units is set at an active level of the first control terminal during an end phase of a duration in which the scan pulse is output at the scan pulse output terminal.

### BRIEF DESCRIPTION OF THE DRAWINGS

In order to more clearly illustrate the technical solutions in the embodiments of the present disclosure, the drawings used in the description of the embodiments will be briefly described below. It is apparent that the drawings in the following description are some of the embodiments of the present disclosure. Other drawings may be derived from these drawings by those of ordinary skill in the art without making any inventive effort.

FIG. 1 is a structural block diagram of a shift register unit according to an embodiment of the present disclosure;

FIG. 2 is a circuit diagram of a shift register unit according to an embodiment of the present disclosure;

FIG. 3 is a schematic diagram of a cascade of shift register units between gate lines;

FIG. 4 is a simulation timing diagram of the shift register unit shown in FIG. 2;

FIG. 5 is an equivalent circuit diagram of a gate line;

FIG. 6 is a schematic diagram of a transition of a drive voltage at a near end and at a far end of a gate line in a typical shift register unit; and

FIG. 7 is a schematic diagram of a transition of a drive voltage at a near end and at a far end of a gate line in a shift register unit according to an embodiment of the present disclosure.

### DETAILED DESCRIPTION

The technical solutions in embodiments of the present disclosure will be described below clearly and thoroughly with reference to the accompanying drawings to render the objectives, technical solutions and advantages of the embodiments of the present disclosure more clear. It is apparent that the described embodiments are part of the embodiments of the present disclosure, not all of them. All other embodiments derived by those of ordinary skill in the art from the embodiments of the present disclosure without paying any inventive effort fall within the scope of this disclosure.

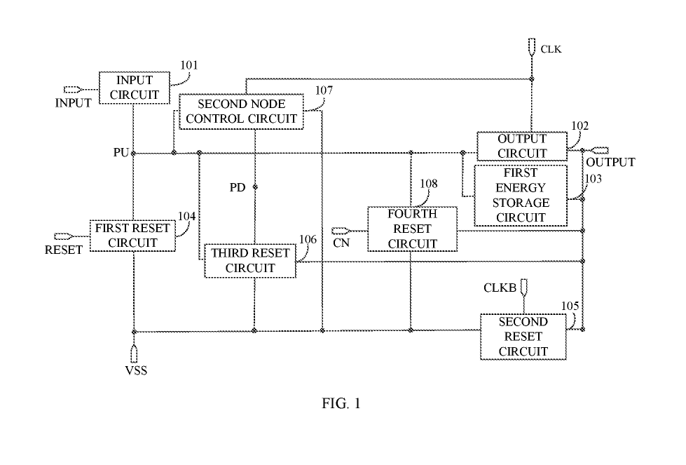

FIG. 1 is a structural block diagram of a shift register unit according to an embodiment of the present disclosure. Referring to FIG. 1, the shift register unit includes an input circuit 101, an output circuit 102, a first storage circuit 103, a first reset circuit 104, a second reset circuit 105, a third reset circuit 106, a fourth reset circuit 108, and a second node control circuit 107. The input circuit 101 is connected to a scan pulse input terminal INPUT and a first node PU, and is used for setting the first node PU at a first level when the scan pulse input terminal INPUT is at the first level. The output circuit 102 is connected to the first node PU, a first clock signal terminal CLK, and a scan pulse output terminal OUTPUT, and is adapted to bring the first clock signal input terminal CLK and the scan pulse output terminal OUTPUT into conduction when the first node PU is at the first level. The first energy storage circuit 103 is connected to the first node PU and the scan pulse output terminal OUTPUT, and is used for maintaining charges of the first node PU when the first node PU is floated. The first reset circuit 104 is connected to a reset control terminal RESET, the first node PU and a second level direct current voltage terminal VSS, and is used for bringing the first node PU and the second level direct current voltage terminal VSS into conduction when the reset control terminal RESET is at the first level. The second reset circuit 105 is connected to a second clock signal terminal CLKB, the scan pulse output terminal OUTPUT and the second level direct current voltage terminal VSS, and is used for bringing the scan pulse output terminal OUTPUT and the second level direct current voltage terminal VSS into conduction when the second clock signal terminal CLKB is at the first level. The third reset circuit 106 is connected to the first node PU, a second node PD, the scan pulse output terminal OUTPUT and the second level direct current voltage terminal VSS, and is used for bringing each of the first node PU and the scan pulse output terminal VSS into conduction with the second level direct current voltage terminal VSS when the second node PD is at the first level. The second node control circuit 107 is connected to the first clock signal terminal CLK, the first node PU, the second node PD, and the second level direct current voltage terminal VSS, and is used for bringing the second node PD and the second level direct current voltage terminal VSS into conduction when the first node PU is at the first level, and for bringing the first clock signal terminal CLK and the second node PD into conduction when the first clock signal terminal CLK is at the first level. The fourth reset circuit 108 is connected to a first control terminal CN, the first node PU, the scan pulse output terminal OUTPUT and the second level direct current voltage terminal VSS, and is used for bringing each of the first node PU and the scan pulse output terminal OUTPUT into conduction with the second level direct current voltage terminal VSS when the first control terminal CN is at an active level.

It is to be understood that those input to the first clock signal CLK and the second clock signal CLKB are a set of clock signals which are mutually phase-inverted with respect to each other. For example, when the “positive phase clock signal” is at a high level, the “inverted clock signal” is at low level. Inputting to the first control terminal CN is started at a preset time before the end of the signal output by the scan pulse output terminal OUTPUT, to pull the signal output by the scan pulse output terminal OUTPUT in the preset time. The second level may be a low level. The first level is a high level relative to the second level. The active level is higher than the second level and may be a high level as long as the potential of the first node PU and the scan pulse output terminal OUTPUT can be pulled down.

According to embodiments of the present disclosure, by way of a configuration of the fourth reset circuit 108 in the shift register unit, applying an active level of the fourth reset circuit 108 on the first control terminal CN during an end phase of a duration in which a scan pulse is output at the scan pulse output terminal OUTPUT allows the fourth reset circuit 108 to pull down an amplitude of a voltage of the scan pulse. In this way, angle-cutting of the scan pulse is realized. Thus, it is possible to reduce a voltage difference from a near end to a far end of a gate line, leading to reduction of a difference between a near-end voltage and a far-end voltage on the gate line. Thereby, at the end of the scan pulse, a difference between an amount of voltage transition corresponding to the near end and an amount of voltage transition corresponding to the far end of the gate line is reduced, and a difference between respective amounts of variation ΔVp due to the voltage transitions will be reduced accordingly. In this way, picture flickering due to the difference between the amounts of variation ΔVp is weakened.

As a more optimized solution, the shift register unit further comprises a second energy storage circuit. The second energy storage circuit is connected to the second node and is used to maintain charges of the second node when the second node is suspended. In this way, the second node can be continuously maintained at the first level, so that the first node PU and the scan pulse output terminal OUTPUT are continuously reset.

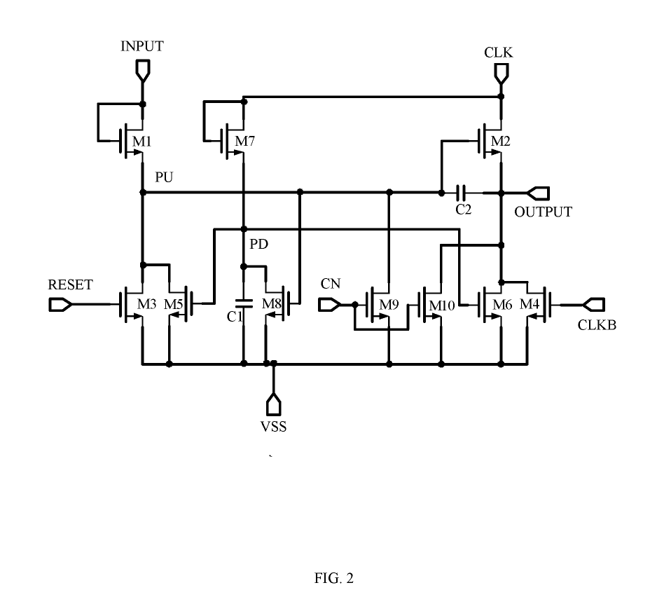

As a more specific embodiment, FIG. 2 shows a circuit diagram of a shift register unit according to an embodiment of the present disclosure. Referring to FIG. 2, the second energy storage circuit is a first capacitor C1. Specifically, one terminal of the first capacitor C1 is connected to the second node PD and the other terminal is connected to the second level direct current voltage terminal VSS.

In the present embodiment, the input circuit 101 includes a first switch transistor M1. The gate of the first switch transistor M1 is connected to the scan pulse input terminal INPUT, the drain is connected to the scan pulse input terminal INPUT, and the source is connected to the first node PU. Moreover, the conduction level is the first level.

By way of this, when the scan pulse input terminal INPUT is connected to the first level, a current flowing to the first node PU can be generated in the first switch transistor M1 to set the potential at the first node PU to the first level. It can be seen that the first switch transistor M1 can realize the function of the input circuit 101 based on the circuit as shown in FIG. 2.

In the present embodiment, the output circuit 102 includes a second switch transistor M2. Specifically, the gate of the second switch transistor M2 is connected to the first node PU, the drain is connected to the first clock signal terminal CLK, and the source is connected to the scan pulse output terminal OUTPUT. In addition, the conduction level is the first level.

The first energy storage circuit 103 specifically includes a second capacitor C2. One terminal of the second capacitor C2 is connected to the first node PU, and the other terminal is connected to the scan pulse output terminal OUTPUT. Thus, when the first node PU is in a floating state, the first node PU may be maintained at the first level.

By way of this, when the first node PU is at the first level, the first clock signal terminal CLK and the scan pulse output terminal OUTPUT are brought into conduction by the second switch transistor M2. In addition, when the first clock signal CLK is at the first level, the signal at the first node PU is output. It can be seen that the second switch transistor M2 can realize the function of the output circuit 102 based on the circuit as shown in FIG. 2.

In the present embodiment, the first reset circuit 104 includes a third switch transistor M3. Specifically, the gate of the third switch transistor M3 is connected to the reset control terminal RESET, the drain is connected to the first node PU, and the source is connected to the second level direct current voltage terminal VSS. In addition, the conduction level is the first level.

By way of this, when the reset control terminal RESET is at the first level, the first node PU and the second level DC voltage terminal VSS are brought into conduction by the third switch transistor M3 to lower the potential at the first node PU. It can be seen that the third switch transistor M3 can realize the function of the first reset circuit 104 based on the circuit as shown in FIG. 2.

In the present embodiment, the second reset circuit 105 includes a fourth switch transistor M4. Specifically, the gate of the fourth switch transistor M4 is connected to the second clock signal terminal CLKB, the drain is connected to the scan pulse output terminal OUTPUT, and the source is connected to the second level direct current voltage terminal VSS. In addition, the on level is the first level.

By way of this, when the second clock signal CLKB is at the first level, the scan pulse output terminal OUTPUT and the second level DC voltage terminal VSS are brought into conduction by the fourth switch transistor M4 to lower the potential of the scan pulse output terminal OUTPUT. It can be seen that the fourth switch transistor M4 can realize the function of the second reset circuit 105 based on the circuit as shown in FIG. 2.

In the present embodiment, the third reset circuit 106 includes a fifth switch transistor M5 and a sixth switch transistor M6. Specifically, the gate of the fifth switch transistor M5 is connected to the second node PD, the drain is connected to the first node PU, and the source is connected to the second level DC voltage terminal VSS. In addition, the conduction level is the first level. Further, the gate of the sixth switch transistor M6 is connected to the second node PD, the drain is connected to the scan pulse output terminal OUTPUT, and the source is connected to the second level direct current voltage terminal VSS. In addition, the conduction level is the first level.

By way of this, when the second node PD is at the first level, the first node PU and the second level DC voltage terminal VSS are brought into conduction by the fifth switch transistor M5 to lower the potential of the first node PU. In addition, the scan pulse output terminal OUTPUT and the second level DC voltage terminal VSS are brought into conduction by the sixth switch transistor M6 to lower the potential of the scan pulse output terminal OUTPUT. It can be seen that the function of the third reset circuit 106 can be realized by the fifth switch transistor M5 and the sixth switch transistor M6 based on the circuit as shown in FIG. 2.

In the present embodiment, the second node control circuit 107 includes a seventh switch transistor M7 and an eighth switch transistor M8. Specifically, the gate of the seventh switch transistor M7 is connected to the first clock signal CLK, the drain is connected to the first clock signal CLK, and the source is connected to the second node PD. The conduction level is the first level. In addition, the gate of the eighth switch transistor M8 is connected to the first node PU, the drain is connected to the second node PD, and the source is connected to the second level DC voltage terminal VSS. The conduction level is the first level.

By way of this, when the first clock signal CLK is at the first level, a current flowing to the second node PD is generated in the seventh switch transistor M7 to set the second node PD at the first level. Further, when the first node PU is at the first level or even higher, the second node PD and the second level DC voltage terminal VSS are brought into conduction by the eighth switch transistor M8 to pull the potential of the second node PD. It can be seen that the function of the second node control circuit 107 can be realized by the seventh switch transistor M7 and the eighth switch transistor M8 based on the circuit shown in FIG. 2.

In the present embodiment, the fourth reset circuit 108 includes a ninth transistor M9 and a tenth transistor M10. Specifically, the gate of the ninth switch transistor M9 is connected to the first control terminal CN, the drain is connected to the first node PU, and the source is connected to the second level DC voltage terminal VSS. The conduction level is an active level. Further, the gate of the tenth switch transistor M10 is connected to the first control terminal CN, the drain is connected to the scan pulse output terminal OUTPUT, and the source is connected to the second level DC voltage terminal VSS. The conduction level is active Level.

By way of this, when the first control terminal CN is at the active level, the first node PU and the second level direct current voltage terminal VSS are brought into conduction by the ninth switch transistor M9 to lower the potential at the first node PU. In addition, the scan pulse output terminal OUTPUT and the second level DC voltage terminal VSS are brought into conduction by the tenth switch transistor M10 to lower the potential of the scan pulse output terminal OUTPUT. Thus, the function of the above-mentioned fourth reset circuit 108 can be realized by the ninth transistor M9 and the tenth transistor M10 based on the circuit shown in FIG. 2.

Further, the first level is a high level, the second level is a low level, and the active level of the fourth reset circuit is a high level.

High and low levels refer to two preset voltage ranges that are higher and lower relative to each other. The values of the high and low levels can be set by those skilled in the art according to the selected device and the circuit structure employed, and are not limited by this disclosure. For example, in FIG. 2, the second level DC voltage terminal VSS, the second level of the first clock signal CLK, the second level of the second clock signal CLKB, and the second level of the first control terminal CN are set to 0V. Further, the first level of the scan pulse input terminal INPUT, the first level of the first clock signal CLK and the first level of the second clock signal CLKB are optionally set to 15 V, and the active level of the first control terminal CN is set to 3V.

It is to be understood that the circuit configuration shown in FIG. 2 is an example, and that substitution for the circuit configuration of any of these circuits can be made by those skilled in the art on a premise that their respective functions are realized. The present disclosure is not so limited.

It should be noted that the connection between the source and the drain of each switch transistor has been specifically described in FIG. 2. However, the connection of the source and the drain may be interchanged in order to accommodate the settings of the first level, the second level and the active level at the respective circuit nodes. This disclosure is not so limited. In particular, when the transistor has a structure in which the source and the drain are symmetrical, the source and the drain can be regarded as two electrodes that do not make a particular difference.

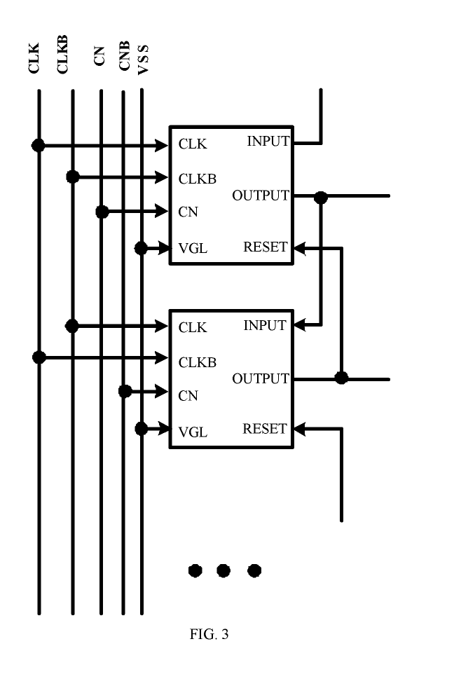

FIG. 3 is a schematic diagram of a cascade of shift register units shown in FIG. 2 between gate lines. Referring to FIG. 3, among the gate lines, the clock signals input to the first clock signal CLK of the previous shift register unit and the first clock signal CLK of the next shift register unit is a set of clock signals that are phase-inverted with respect to each other. In addition, in each of the shift register units, an active level for realizing angle cutting is input to the first control terminal CN before the first level input by the first clock signal CLK of the shift register unit transitions to the second level (e.g., in FIG. 2, the level input at the first control terminal CN is 3V).

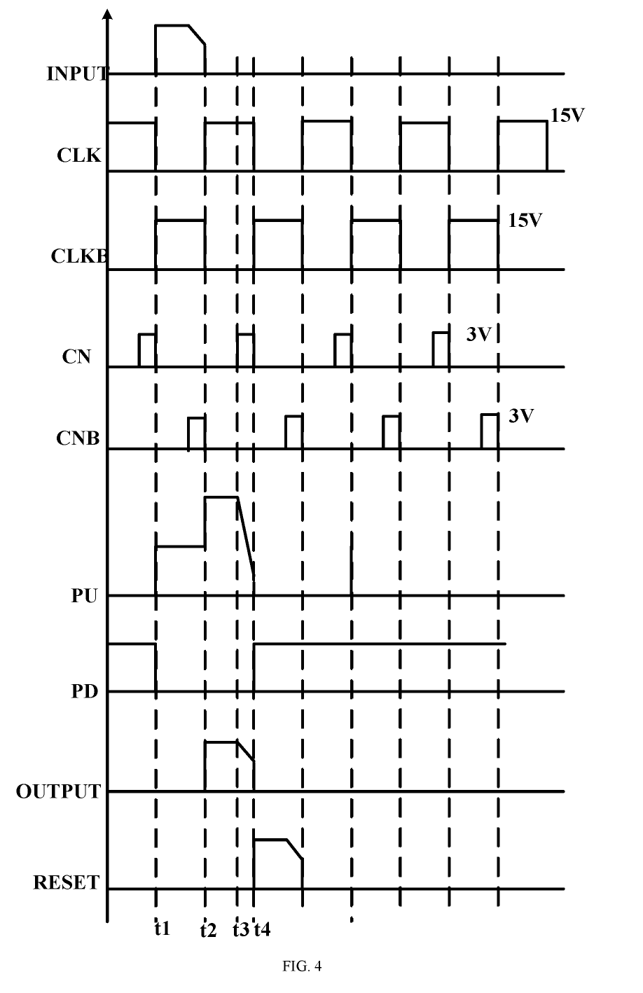

FIG. 4 is a simulation timing diagram of the shift register unit shown in FIG. 2. In connection with FIG. 4, it can be seen that a signal is input to the scan pulse input terminal INPUT of the shift register unit (e.g., the first shift register unit in FIG. 3) during periods t1-t2. The signal is an angle-cut signal and is input by the scan pulse output terminal OUTPUT of the previous register unit. At this time, the second clock signal CLKB is at a high level to reset the scan pulse output terminal OUTPUT of the shift register unit.

During periods t1-t2, the first switch transistor M1 (see FIG. 2) in the shift register unit is turned on, and the first node PU is pulled high. In addition, since the first clock signal CLK is at a low level, the first node PU is stabilized at a high level by means of the second capacitor C1.

During periods t2-t3, the first clock signal CLK is at high level and a current flowing to the scan pulse output terminal OUTPUT is generated in the second switch transistor M3. This causes the scan pulse output terminal OUTPUT to output a high level. At the same time, the potential at the first node PU is further pulled high (see FIG. 4) under the self-boosting effect of the second capacitor C2.

During periods t2-t3, a level of 3V is input to the first control terminal CN, so that the ninth transistor M9 and the tenth transistor M10 are turned on. The ninth transistor M9 pulls down the potential at the first node PU, and the tenth transistor M10 pulls down the high level of the output of the scan pulse output terminal OUTPUT (see FIG. 4) so that the amplitude of the scan pulse output by the scan pulse output terminal OUTPUT is pulled down in advance.

The signal output by the shift pulse output terminal OUTPUT of the shift register unit is used as an input signal to the scan pulse input terminal INPUT of the next shift register unit. The signal output by the scan pulse output terminal OUTPUT of the next shift register unit is used as a signal to the reset control terminal RESET of the shift register unit. Therefore, the shift register unit is reset by the signal output from the scan pulse output terminal OUTPUT of the next shift register unit in the next clock cycle after signal outputting at the shift pulse output terminal OUTPUT of the present shift register unit. Thus, the first node PU is reset by the high level input from the reset control terminal RESET.

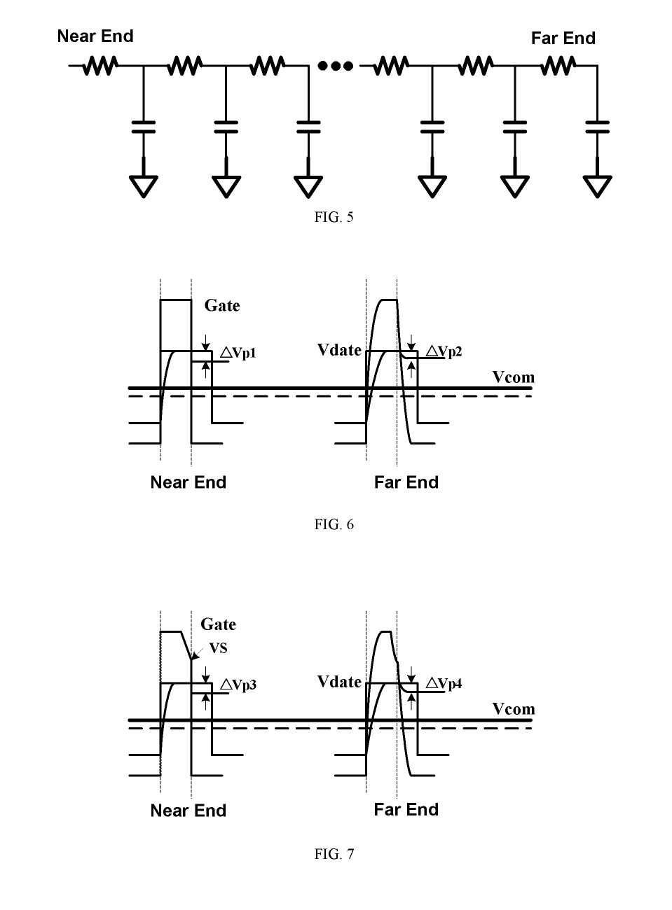

An equivalent circuit of the gate line in an actual LCD display is shown in FIG. 5. It can be seen that there is a large amount of capacitive reactance and impedance on the gate line, and that the equivalent circuit is equivalent to an RC circuit. Due to a delay effect of the RC circuit on the gate line, there is a difference between the scan pulse at the near end and at the far end of the gate line in its amount of transition in voltage transitioning. The variation caused to the signal on a corresponding data line is ΔVp1 at the near end of the gate line which is less affected by the load, and the variation caused to the signal on a corresponding data line is ΔVp2 at the far end of the gate line which is more affected by the load. There is a big difference between ΔVp1 and ΔVp2 as shown in FIG. 6. However, in the present embodiment, since the amplitude of the output scan pulse is pulled down in advance at an end phase of a duration in which the scan pulse output terminal outputs the scan pulse, the difference between the amount of change in the scan pulse at the near end and the far end of the gate line is reduced. Thus, the effect of the change in the voltage at the near end and the far end of the gate line on the signal on the data line is reduced. In this way, the flickering at the near end and the far end of the gate line due to the influence of the gate line load is eliminated, and the picture quality of the display is not affected.

FIG. 6 is specifically a schematic diagram of the transition of a drive voltage at a near end and a far end of a gate line in a typical shift register unit. Referring to FIG. 6, at the near end, the voltage on the gate line drops from V_{GH} to V_{GL}, where the amount of voltage transition ΔVg₁=V_{GL}−V_{GH}. At the far end, the initial voltage of the gate line is V_{GH}′ due to the delay effect of the RC circuit. Thus, in voltage transitioning, the amount of voltage transition ΔVg₂=V_{GL}−V_{GH}′ at the far end. Assuming that the changes in the data voltage due to ΔVg₁ and ΔVg₂ at the near and far ends are ΔVp1 and ΔVp2, respectively, when the difference between ΔVg₁ and ΔVg₂ (V_{GH}−V_{GH}′) is large, the difference between ΔVp1 and ΔVp2 will be large. This means that the amount of voltage change in the data voltage is proportional to the amount of change in the voltage on the gate line. As a result, flickering occurs during display, and the display quality is affected. FIG. 7 is a schematic diagram of the transition of a drive voltage at a near end and a far end of a gate line in a shift register unit according to an embodiment of the present disclosure. Referring to FIG. 7, the voltage drops to VS after angle-cutting of the scan pulse, and the voltage at the far end is VS′. Since VS is less than V_{GH}, the difference between VS and VS′ is less than the difference between V_{GH} and V_{GH}′ (because the voltage difference due to the resistance of the gate line is proportional to the voltage input to the gate line in the case where the resistance of the gate line is constant). Accordingly, the difference VS−VS′ between the amount of voltage transition ΔVg₃ corresponding to the near end and the amount of voltage transition ΔVg₄ corresponding to the far end is also small in the voltage transitioning. Accordingly, the difference between the amounts of variation of the data voltages ΔVp3 and ΔVp4 at the near and far ends will be small. In this way, it is possible to advantageously weaken the flickering at the near and far ends of the gate lines.

It can be seen that according to the embodiments of the present disclosure, by way of a configuration of the fourth reset circuit in the shift register unit, applying an active level of the fourth reset circuit on the first control terminal CN during an end phase of a duration in which a scan pulse is output at the scan pulse output terminal OUTPUT allows the fourth reset circuit to pull down an amplitude of a voltage of the scan pulse. In this way, angle-cutting of the scan pulse is realized. Thus, it is possible to reduce a voltage difference from a near end to a far end of a gate line, leading to reduction of a difference between a near-end voltage and a far-end voltage on the gate line. Thereby, at the end of the scan pulse, a difference between an amount of voltage transition corresponding to the near end and an amount of voltage transition corresponding to the far end of the gate line is reduced. A difference between respective amounts of variation ΔVp due to the voltage transitions will be reduced accordingly, thus weakening picture flickering due to the difference between the amounts of variation ΔVp.

An embodiment of the present disclosure further provides a gate driving circuit based on the same concept. The gate driving circuit includes a plurality of any of the shift register units as described that are cascaded with each other.

In the gate driving circuit according to the present embodiment, the output level is pulled down during an end phase of a duration in which the output terminal of each of the shift register units outputs the scan pulse, thereby reducing the difference between the amounts of transition of the gate driving voltage at the near end and the far end. As a result, the flickering is reduced, and the display quality is improved.

Of course, the gate driving circuit according to the present embodiment may further include a base substrate and a display substrate formed on the base substrate by a film-forming process. The gate driving circuit is formed in the display substrate. Since the difference between the changes in the scan pulse at the near and far ends of the gate line is reduced, the flickering at the near and far ends of the gate line due to the influence of the gate line load in the GOA circuit is avoided, and the quality of the image displayed is further improved. The display apparatus includes any of the above-mentioned gate driving circuits. It should be noted that the display apparatus may be any product or component having a display function such as a display panel, an electronic paper, a mobile phone, a tablet computer, a television set, a notebook computer, a digital photo frame, a navigator, or the like.

According to another aspect, embodiments of the present disclosure also provide a driving method for the gate driving circuit described above. The driving method includes inputting a start pulse to the input terminal of a first one of the shift register units, and inputting corresponding clock signals to the first clock signal terminals and the second clock signal terminals so that the gate driving circuit sequentially outputs a plurality of scan pulses. The driving method further includes inputting a clock signal to the first control terminal of each of the shift register units so that the first control terminal of each of the shift register units is set at an active level of the first control terminal during an end phase of a duration in which the scan pulse is output at the scan pulse output terminal.

Referring to FIGS. 2, 3 and 4, in the embodiments, the start pulse may be a pulse signal output at the scan pulse output terminal of the previous shift register unit, or may be a customized initial pulse, as long as the first node can be set at a high level in the t1-t2 period.

The inputs to the first clock signal terminals and the second clock signal terminals are two signals which have opposite phases at any time with respect to each other. The magnitude of the pulse signal input at the first control terminals may depend on the actual circuit.

It can be seen that according to the driving method of the gate driving circuit provided in the embodiments of the present disclosure, by way of a configuration of the fourth reset circuit in the shift register unit, applying an active level of the fourth reset circuit on the first control terminal CN during an end phase of a duration in which a scan pulse is output at the scan pulse output terminal OUTPUT allows the fourth reset circuit to pull down an amplitude of a voltage of the scan pulse. In this way, angle-cutting of the scan pulse is realized. Thus, it is possible to reduce a voltage difference from a near end to a far end of a gate line, leading to reduction of a difference between a near-end voltage and a far-end voltage on the gate line. Thereby, at the end of the scan pulse, a difference between an amount of voltage transition corresponding to the near end and an amount of voltage transition corresponding to the far end of the gate line is reduced. A difference between respective amounts of variation ΔVp due to the voltage transitions will be reduced accordingly, thus weakening picture flickering due to the difference between the amounts of variation ΔVp.

It is to be noted that, in the description of the present disclosure, terms such as “upper”, “lower”, etc. indicating azimuth or positional relationship are used based on the azimuth or positional relationship shown in the drawings for the purpose of facilitating and simplifying the description of the present disclosure, rather than used to indicate or imply that the device or element referred to must have a specific orientation, or be constructed and operated in a particular orientation. Accordingly, they are not to be construed as limiting the present disclosure. Unless otherwise expressly stated and defined, the terms “install”, “couple” and “connect” shall be broadly understood. For example, it may be a fixed connection, or may be a detachable connection, or may be connected integrally. It may be a mechanical connection or an electrical connection. It may be a direct connection, an indirect connection through an intermediate medium, or an internal communication between two elements. The specific meaning of the above terms in the present disclosure may be understood by those of ordinary skill in the art in light of specific circumstances.

In the specification of the present disclosure, numerous specific details are described. It will be understood, however, that the embodiments of the present disclosure may be practiced without these specific details. In some instances, well-known methods, structures, and techniques have not been shown in detail so as not to obscure the understanding of this specification.

Similarly, it is to be understood that in the exemplary embodiments of the present disclosure as described above the features of the present disclosure are sometimes grouped together into a single embodiment in order to simplify the disclosure and to assist in understanding one or more of the various disclosed aspects. However, this disclosure should not be construed as reflecting the intention that the claimed disclosure requires more features than those specifically recited in each claim. More specifically, as reflected in the claims, there may be less than all the features of the previously disclosed single embodiment. Accordingly, the claims that follow the specific embodiments are expressly incorporated into this detailed description, wherein each claim is treated as an individual embodiment of the present disclosure.

It should be noted that the above embodiments illustrate the present disclosure and are not intended to be limiting of the present disclosure. Moreover, alternative embodiments may be devised by those skilled in the art without departing from the scope of the appended claims. In the claims, any reference signs between parentheses should not be construed as limiting the claims. The word “comprising” does not exclude the presence of elements or steps not listed in the claims. The word “a” or “an” preceding the element does not exclude the presence of a plurality of such elements. The present disclosure may be implemented by means of hardware comprising several different elements and by means of a suitably programmed computer. In a single claim enumerating several devices, several of these devices may be embodied by the same hardware item. The use of words first, second, and third is not indicative of any order. These words can be interpreted as names.

The foregoing is merely specific embodiments of the present disclosure and is not intended to limit the present disclosure. It will be apparent to those skilled in the art that various changes and modifications may be made to this disclosure. Any modifications, equivalent substitutions, improvements, and the like within the spirit and principles of this disclosure are intended to be encompassed within the scope of the present disclosure.

1. A shift register unit comprising an input circuit, an output circuit, a first energy storage circuit, a first reset circuit, a second reset circuit, a third reset circuit, a fourth reset circuit, and a second node control circuit, wherein
the input circuit is connected to a scan pulse input terminal and a first node for setting the first node at a first level in response to the scan pulse input terminal being at the first level;
the output circuit is connected to the first node, a first clock signal terminal, and a scan pulse output terminal for bringing the first clock signal input terminal and the scan pulse output terminal into conduction in response to the first node being at the first level;
the first energy storage circuit is connected to the first node and the scan pulse output terminal for maintaining charges of the first node in response to the first node being floated;
the first reset circuit is connected to a reset control terminal, the first node and a second level direct current voltage terminal for bringing the first node and the second level direct current voltage terminal into conduction in response to the reset control terminal being at the first level;
the second reset circuit is connected to a second clock signal terminal, the scan pulse output terminal and the second level direct current voltage term urinal for bringing the scan pulse output terminal and the second level direct current voltage terminal into conduction in response to the second clock signal terminal being at the first level;
the third circuit is connected to the first node, a second node, the scan pulse output terminal and the second level direct current voltage terminal for bringing the first node and the second level direct current voltage terminal into conduction, and the scan pulse output terminal and the second level direct current voltage terminal into conduction, in response to the second node being at the first level;
the second node control circuit is connected to the first clock signal terminal, the first node, the second node, and the second level direct current voltage terminal for bringing the second node and the second level direct current voltage terminal into conduction in response to the first node being at the first level, and for bringing the first clock signal terminal and the second node into conduction in response to the first clock signal terminal being at the first level; and
the fourth reset circuit is connected to a first control terminal, the first node, the scan pulse output terminal and the second level direct current voltage terminal for bringing the first node and the second level direct current voltage terminal into conduction, and the scan pulse output terminal and the second level direct current voltage terminal into conduction, in response to the first control terminal being at an active level of the fourth reset circuit.

2. The shift register unit of claim 1, further comprising a second energy storage circuit connected to the second node for maintaining charges of the second node in response to the second node being floated.

3. The shift register unit of claim 2, wherein the second energy storage circuit comprises a first capacitor, one terminal of the first capacitor being connected to the second node and the other to the second level direct current voltage terminal.

4. The shift register unit of claim 1, wherein the input circuit comprises a first switch transistor, a gate of the first switch transistor being connected to the scan pulse input terminal, one of a source and a drain of the first switch transistor being connected to the scan pulse input terminal and the other to the first node, and wherein a conduction level of the first switch transistor is the first level.

5. The shift register unit of claim 1, wherein the output circuit comprises a second switch transistor, a gate of the second switch transistor being connected to the first node, one of a source and a drain of the second switch transistor being connected to the first clock signal terminal and the other to the scan pulse output terminal, and wherein a conduction level of the second switch transistor is the first level.

6. The shift register unit of claim 1, wherein the first energy storage circuit comprises a second capacitor.

7. The shift register unit of claim 1, wherein the first reset circuit comprises a third switch transistor, a gate of the third switch transistor being connected to the reset control terminal, one of a source and a drain of the third switch transistor being connected to the first node and the other to the second level direct current voltage terminal, and wherein a conduction level of the third switch transistor is the first level.

8. The shift register unit of claim 1, wherein the second reset circuit comprises a fourth switch transistor, a gate of the fourth switch transistor being connected to the second clock signal terminal, one of a source and a drain of the fourth switch transistor being connected to the scan pulse output terminal and the other to the second level direct current voltage terminal, and wherein a conduction level of the fourth switch transistor is the first level.

9. The shift register unit of claim 1, wherein the third reset circuit comprises a fifth switch transistor and a sixth switch transistor, wherein
a gate of the fifth switch transistor is connected to the second node, one of a source and a drain of the fifth switch transistor is connected to the first node and the other to the second level direct current voltage terminal, and a conduction level of the fifth switch transistor is the first level; and
a gate of the sixth switch transistor is connected to the first node, one of a source and a drain of the sixth switch transistor is connected to the scan pulse output terminal and the other to the second level direct current voltage terminal, and a conduction level of the sixth switch transistor is the first level.

10. The shift register unit of claim 1, wherein the second node control circuit comprises a seventh switch transistor and an eighth switch transistor, wherein
a gate of the seventh switch transistor is connected to the first clock signal terminal, one of a source and a drain of the seventh switch transistor is connected to the first clock signal terminal and the other to the second node, and a conduction level of the seventh switch transistor is the first level; and
a gate of the eighth switch transistor is connected to the first node, one of a source and a drain of the eighth switch transistor is connected to the second node and the other to the second level direct current voltage terminal, and a conduction level of the eighth switch transistor is the first level.

11. The shift register unit of claim 1, wherein the fourth reset circuit comprises a ninth transistor and a tenth transistor, wherein
a gate of the ninth switch transistor is connected to the first control terminal, one of a source and a drain of the ninth switch transistor is connected to the first node and the other to the second level direct current voltage terminal, and a conduction level of the ninth switch transistor is the active level; and
a gate of the tenth switch transistor is connected to the first control terminal, one of a source and a drain of the tenth switch transistor is connected to the scan pulse output terminal and the other to the second level direct current voltage terminal, and a conduction level of the tenth switch transistor is the active level.

12. The shift register unit of claim 1, wherein the first level comprises a high level, wherein the second level comprises a low level, and wherein the active level of the fourth reset circuit comprises a high level.

13. A gate driving circuit comprising a plurality of cascaded shift register units each comprising the shift register unit as claimed in claim 1.

14. A driving method for the gate driving circuit of claim 13, comprising:
inputting a start pulse to the scan pulse input terminal of a first one of the shift register units;
inputting corresponding clock signals to the first clock signal terminals and the second clock signal terminals of the shift register units so that the gate driving circuit sequentially outputs a plurality of scan pulses; and
inputting a clock signal to the first control terminal of each of the shift register units so that the first control terminal of each of the shift register units is set at an active level of the first control terminal during an end phase of a duration in which the scan pulse is output at the scan pulse output terminal.
